(19) United States
(12) Patent Application Publication
(10) Pub. No.: US 2005/0127500 A1
(43) Pub. Date: Jun. 16, 2005

(54) Local reduction of compliant thermally conductive material layer thickness on chips

(75) Inventors: Evan G. Colgan, Chestnut Ridge, NY (US); Claudis Feger, Poughkeepsie, NY (US); Gary F. Goth, Pleasant Valley, NY (US); George A. Katopis, Poughkeepsie, NY (US); John H. Magerlein, Yorktown Heights, NY (US); Edmund J. Sprogis, Underhill, VT (US)

Correspondence Address: Philmore H. Colburn II;Cantor Colburn LLP, 55 Griffin Road South, Bloomfield, CT, 06002, US

(73) Assignee: International Business Machines Corporation, Armonk, NY (US)

(21) Appl. No.: 10/732,015

(22) Filed: Dec. 10, 2003

(51) Int. Cl. H01L 23/10

(52) U.S. Cl. 257/706

(57) ABSTRACT

In an integrated circuit packaging structure, such as in an MCM or in a SCM, a compliant thermally conductive material is applied between a heat-generating integrated circuit chip and a substrate attached thereto. Raised regions are defined on the back side of the chip aligned to areas of a higher than average power density on the front active surface of the chip such that a thinner layer of the compliant thermally conductive material is disposed between the chip and the substrate in this area after assembly thereof resulting in a reduced “hot-spot” temperature on the chip. In an exemplary embodiment, the substrate includes one of a heat sink, cooling plate, thermal spreader, heat pipe, thermal hat, package lid, or other cooling member.

### CROSS-REFERENCE TO RELATED APPLICATIONS

This application contains subject matter which is related to the subject matter of the following co-pending application, which is assigned to the same assignee as this application, International Business Machines Corporation of Armonk, N.Y. An application entitled “Improvement in chip cooling” having attorney docket number YOR920020329US1 filed on Dec. 27, 2002, is hereby incorporated herein by reference in its entirety.

### TECHNICAL FIELD

This invention relates to cooling within integrated circuit (IC) packaging structures. More particularly, the present invention is directed to the cooling of integrated circuit chips using a relatively thick compliant thermally conductive material where there is a nonuniform power distribution on the integrated circuit.

### BACKGROUND OF THE INVENTION

As heat is generated during the functioning of integrated circuit chips (ICs), the thermal resistance to the heat sink must be small so that the operating temperature of the chip is low enough to assure the continued reliable operation of the device. The problem of heat removal becomes more difficult as chip geometries are scaled down and operating speeds are increased, resulting in increased power density. The ability to adequately cool the chips is therefore a limiting factor in the further increase of system performance. Integrated circuit chips mounted on substrates, and particularly in an array on a substrate such as is found in a multi-chip module (MCM), present special cooling difficulties. In an MCM, the chips may be mounted very close together and nearly cover the whole top surface of the MCM. With such an arrangement, it may not be possible to use a heat spreader bonded directly to the back surface of the chips, as is sometimes used for isolated chips, to reduce the heat flux (power/unit area, i.e. W/cm²). An additional problem is that the processor, and other chips, frequently have a “hot spot” which can have a heat flux significantly greater than the average heat flux resulting in temperatures of about 20° C. hotter than the average chip temperature. A thermal solution which maybe adequate for the average chip power density may not be adequate to allow reliable operation of the hot spot region of the chip.

A common technique for removing heat from high-power IC's makes use of a cooling plate or heat sink which is thermally attached to the chips using a compliant thermally conductive material. Heat is removed from the cooling plate or heat sink by methods such as forced air cooling or circulating liquid coolants. Due to the difference in thermal expansion between the chip and the material of the cooling plate or heat sink, a compliant thermally conductive material is required therebetween. This is especially true for MCMs where an array of chips is mounted on a common substrate and power cycling can result in both vertical and horizontal deflections of the cooling plate relative to the back surface of the IC's. For a chip in a single chip module (SCM) type package, a thermal spreader composed of a high thermal conductivity material with a thermal expansion coefficient close to that of Si, such as SiC, is sometimes bonded to the chip using a silver (Ag) filled epoxy or other thermally conductive adhesive. Due to the close thermal expansion match, a rigid bond with an adhesive can be used, as a compliant layer therebetween is not needed. A heat sink is then mounted onto the thermal spreader using a layer of a compliant thermally conductive material. As an alternative for single chip modules, where mechanical deflections are minimized and the package structure keeps the two surfaces very parallel to each other, a very thin layer, such as 25 microns or less, of a compliant thermally conductive material can be used.

Compliant thermally conductive materials are typically thermal pastes, or thermal greases and are frequently referred to as thermal interface materials (TIMs). Thermally conductive pastes typically comprise thermally conductive particles having a distribution of sizes dispersed within a binder material or matrix, such as the paste described in U.S. Pat. No. 5,098,609 issued Mar. 24, 1992 to Iruvanti et al. In the '609 patent, paste is applied between the top of the IC mounted on the substrate and the lower flat surface of a cooling plate facing the substrate. Typical TIMs include those having a wax matrix, commonly known as phase-change materials, those having a silicone-based matrix, and dry particle lubricants such as graphite and metal powders.

When applying a compliant thermally conductive material between the back of a chip which is electrically attached to a substrate and the lower surface of a cooling plate or heat sink, the compliant thermally conductive material layer is preferably made as thin as possible in order to reduce the thermal resistance through the layer. The compliant thermally conductive material is preferably flexible, maintains its integrity, surface adhesion and chip coverage despite the expansion and contractions of the packaging structure caused by power and temperature cycling. A difficulty observed with the use of compliant thermally conductive materials is the migration of the material from behind the chip and the formation of voids due to differential thermal expansion of the various parts of the package during power and temperature cycling. Such migration of the compliant thermally conductive material can greatly increase the thermal resistance between the chip and the cooling plate or heat sink during the lifetime of the electronic package, possibly causing catastrophic heating and failure of the chip. This migration of the compliant thermally conductive material limits the minimum thickness of material being required to insure reliable operation, with thinner gaps resulting in earlier failures. This critical thickness is a function of the amount of expansion and contraction present in the package, the chip size, the properties of the compliant thermally conductive material, the expected operating life of the package, along with other factors.

In U.S. Pat. No. 5,825,087 issued Oct. 20, 1998 to Iruvanti et al. and assigned to the present assignee, the cooling plate used in conjunction with a thermal paste or thermal adhesive has been roughened by grit blasting or provided with a plurality of crisscrossing channels in order to improve the adhesion of the thermal medium and inhibit its flow during operation of the electronic module.

In U.S. Pat. No. 5,247,426 issued Sep. 21, 1993 to Hamburgen and Fitch, an apparatus comprising a non-uniform thermal conductance structure which includes high thermal conductance regions and low thermal conductance regions is disclosed where the apparatus is coupled to a semiconductor to establish a desirable temperature profile across the surface of the semiconductor. FIG. 1, taken from the prior art '426, shows a side view of a semiconductor 20 which includes, high temperature regions 22, low temperature regions 24, and average temperature regions 26. It should be appreciated that the heat is generated on the non-attached surface of the semiconductor 20, opposite the adhesive 52. The substrate 50 includes a “trench profile” which creates a corresponding trench profile for the adhesive 52. The trench profile includes an upper plateau 54, and middle plateau 56, and a lower plateau 58. The thickness of the adhesive layer is varied to achieve a better thermal distribution over the surface of the semiconductor. A disadvantage of this structure is that it does not provide any compliance, or mechanical stress relief, between the chip and the substrate to which the back of the chip is attached since an adhesive is used. Furthermore, the size of chip with which this type of a structure can be used is limited by the thermal expansion mismatch between the substrate material and the semiconductor since a rigid adhesive join is used. Additionally, the vertical profile of the structure used is undesirable as it is difficult to fill with a compliant thermally conductive material without voids and causes a discontinuity during flow of a compliant thermally conductive material.

U.S. Pat. No. 5,623,394 issued Apr. 22, 1997 to Sherif et al. and assigned to the present assignee, is directed at customizing the cooling of different chips on a MCM by using a plurality of thermally conductive materials. U.S. Pat. No. 5,757,620 issued May 26, 1998 to Edwards et al. and assigned to the present assignee, is also directed at customizing the cooling of different chips on a MCM by varying the depth of thermal compound filled gaps, or blind hole that is above each chip. Both of these do not address the problem of needing a reduced thermal resistance at the “hot-spot” of a chip but are directed at adjusting the thermal resistance only at the chip level.

In U.S. Pat. No. 5,668,404 issued Sep. 16, 1997 to Abe and Ohmae, a semiconductor device includes a semiconductor chip attached to a lead frame with recesses on the rear surface of the semiconductor chip opposite the lead frame. These recesses increase the heat radiation area of the semiconductor chip. FIG. 2, taken from prior art '404, is a cross-sectional view of a semiconductor device where semiconductor chip 20 is encapsulated with a molding resin 5 and the recesses 21 and step 22 formed on the back surface of semiconductor chip 20 increase the contact area between the chip 20 and the molding resin 5. Since there is no alignment between the “hot-spot” on the chip and the microstructure formed on the back side of the chip, this does not reduce the thermal resistance at the hot-spot of a chip. In fact, given that the thermal conductivity of a molding resin is significantly less than that of a typical semiconductor such as silicon, unless there is an extremely high thermal interface resistance between the molding resin and the silicon or the thickness of the molding resin layer is reduced by the presence of the microstructure formed on the back side of the chip, the thermal resistance from the chip to the ambient or a heat sink will not be reduced by the presence of the microstructure. This type of packaging based on lead frames and encapsulation with a molding resin is not suitable for high power and high performance ICs.

U.S. Pat. No. 6,255,695 issued May 1, 2001 to Chia et al. relates to a flip-chip semiconductor package where the non-active surface of the semiconductor die has a plurality of grooves formed thereon; and a heat sink attached to the non-active surface of the semiconductor die with an adhesive. The grooves increase the contact area of the adhesive to the chip, thereby increasing the mechanical bond strength and thermal conductivity between the semiconductor die and the heat sink. FIG. 3, taken from '695, is a cross-sectional view of a flip-chip package where the semiconductor die 310 is provided with a number of grooves 316, the solder bumps 314 are encapsulated by underfill 312 and the non-active side of semiconductor die 310 is coupled to heat sink 304 by adhesive 308. There are a number of disadvantages with this approach, one is that this structure does not provide any compliance, or mechanical stress relief, between the semiconductor die and the heat sink since an adhesive is used, and secondly, the size of chip with which this type of a structure can be used is limited by the thermal expansion mismatch between the semiconductor die and the heat sink material since a rigid adhesive join is used. Furthermore, since there is no alignment between the “hot-spot” on the chip and the grooves formed on the back side of the chip, this does not reduce the thermal resistance at the hot spot of a chip. In fact, given that the thermal conductivity of an adhesive is significantly less than that of a typical semiconductor such as silicon, unless there is an extremely high thermal interface resistance between the adhesive and the silicon or the thickness of the adhesive layer between the semiconductor die and the heat sink is reduced by the presence of the grooves formed on the back side of the chip, the thermal resistance from the die to the heat sink will not be reduced by the presence of the grooves.

A publication entitled “Using cap-integral standoffs to reduce chip hot-spot temperatures in electronic packages”, 2002 Inter Society Conference on Thermal Phenomena, IEEE 2002, pp. 173-178, by M. S. June & K. K. Sikka, who are both employed by the present assignee, and the subject matter of which issued as U.S. Pat. No. 6,294,408 entitled “Method for Controlling Thermal Interface Gap Distance” and assigned to the present assignee, presents a technique of reducing the chip hot-spot temperatures using cap integral standoffs. For an advanced thermal paste interface in a high power electronic module dissipating 100 W, standoffs can reduce the hot-spot temperature by 5-10° C. The standoffs are essentially columns of a high thermal conductivity material in parallel with a relatively low conductivity material. Each standoff will either directly contact the chip or will have an extremely thin interface between itself and the chip. This is due to the low cross sectional area of the standoff which tends to displace any paste that gets under the standoff. The disadvantages of this approach include the precision machining required on the heat sink to add the standoffs and the requirement to precisely align the standoffs with the desired locations on the chip.

Thus, from the prior art discussed above, it is desired to reduce or eliminate “hot spots” associated with active areas of processing chips, while maintaining a compliant interface between the chip and a substrate (e.g., cold plate, heat sink, or other cooling mechanism) in thermal communication therewith, and to prevent the formation of voids in the compliant thermally conductive material during assembly or subsequent thermal or power cycling.

### SUMMARY OF THE INVENTION

The shortcomings of the prior art are overcome and additional advantages are provided through the provision of forming raised portions on the back surface of an integrated circuit in a pattern which corresponds to the hotter areas on the chip. This results in a projecting “mesa” structure on the back side of the chip so that after module assembly, the thickness of the compliant thermally conductive material layer is locally thinner over the “hot spots”. This results in a local reduction of the thermal resistance and hence a reduced temperature of the hot spot on the chip. By local reduction of the paste layer thickness, the allowable global paste layer thickness can be increased, or maintained at a thicker level, which reduces the likelihood of migration of the compliant thermally conductive material and the formation of voids between the chip and the heat sink or cold plate and insures that adequate mechanical compliance is provided between the chip and the heat sink or cold plate. Additionally, if individual pistons are used (as described in U.S. Pat. No. 6,214,647) to better control the compliant thermally conductive material layer thickness over each chip, additional small raised portions at the corners or along the edges of the chip can be formed to insure that the compliant thermally conductive material layer is uniform and that the piston, or heat sink, or cold plate, is not tilted relative to the chip surface.

While the preferred embodiment references using mesas over high heat flux areas to reduce the maximum temperature of such areas, typically found in the core areas of processor chips, this same technology may be used to locally lower the temperature of specific functional areas of the chip that have serious repercussions if that function fails even though the area may have just average heat flux densities. For instance, a chip function that is non-redundant or difficult for the server to recover from if it fails could have its circuits cooled lower by placing a mesa over this functional area, improving the reliability of these sensitive circuits.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 is prior art, shown as FIG. 4 in U.S. Pat. No. 5,247,426.

FIG. 2 is prior art, shown as FIG. 6 in U.S. Pat. No. 5,668,404.

FIG. 3 is prior art, shown as FIG. 3 in U.S. Pat. No. 6,225,695.

FIG. 4(a) is a cross section elevation view of a prior art processor chip in thermal communication with a thermal hat/heat sink with thermal paste therebetween.

FIG. 4(b) is a cross section elevation view of a prior art processor chip of FIG. 4(a) with the addition of a thermal spreader with an epoxy therebetween and in further thermal contact with the thermal hat/heat sink.

FIG. 5 is a cross section elevation view of an exemplary embodiment of a processor chip having a mesa on a top surface in thermal contact with the thermal hat/heat sink.

FIG. 6 is a schematic perspective view illustrating mesas formed by anisotropic wet etching on the back side of a silicon chip.

FIG. 7 is a schematic perspective view illustrating a solid mesa and a “half-toned” mesa formed by anisotropic wet etching on the back surface of a silicon chip.

FIG. 8 is a schematic perspective view illustrating mesas with microstructure on the top surface formed by anisotropic wet etching on the back surface of a silicon chip.

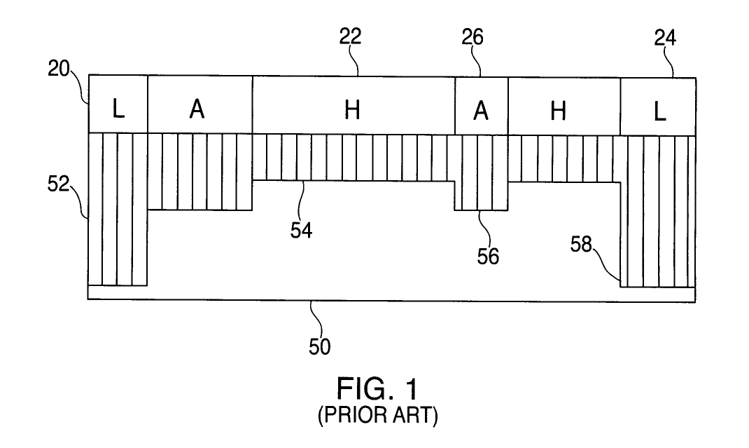

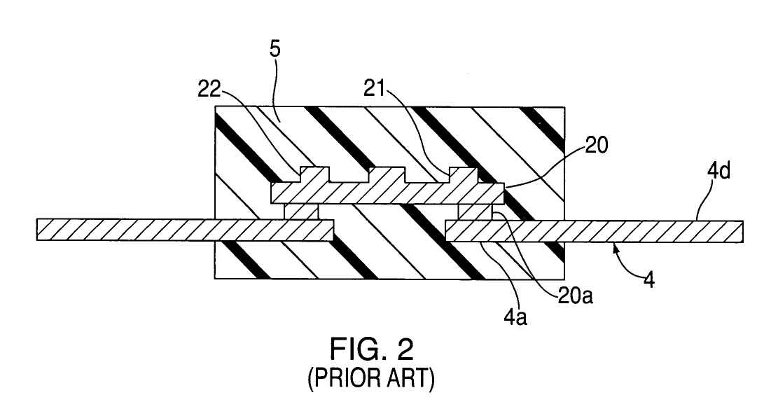

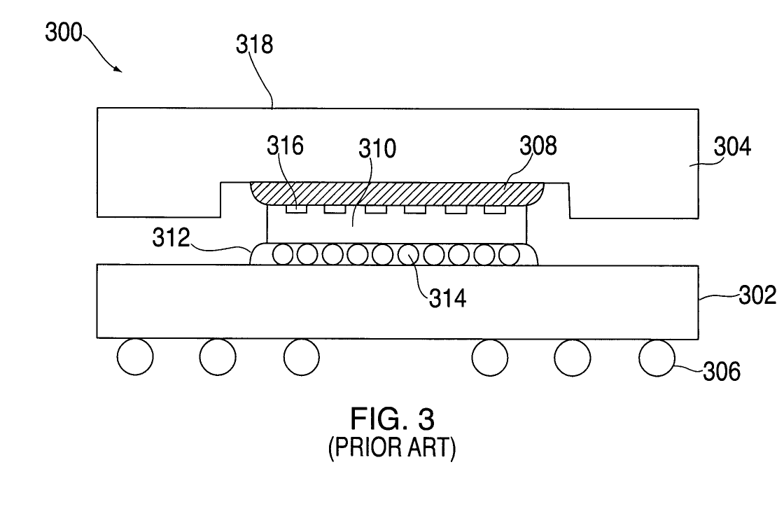

The detailed description explains the preferred embodiments of the invention, together with advantages and features, by way of example with reference to the drawings.

### DETAILED DESCRIPTION OF THE INVENTION

The present invention is directed at locally reducing the thickness of a compliant thermally conductive material in a region or regions aligned with high power density areas on a chip while avoiding migration of the material from behind the chip and the formation of voids.

As transistors are scaled down in size and as the operating frequency increases, the power density (W/cm²) of processor chips will continue to increase. For reliable long-term operation, it is necessary to remove the heat produced by a chip and keep the junction temperatures below about 105° C. Note that the acceptable junction temperature is a function of the technology used and the reliability requirements of the specific product.

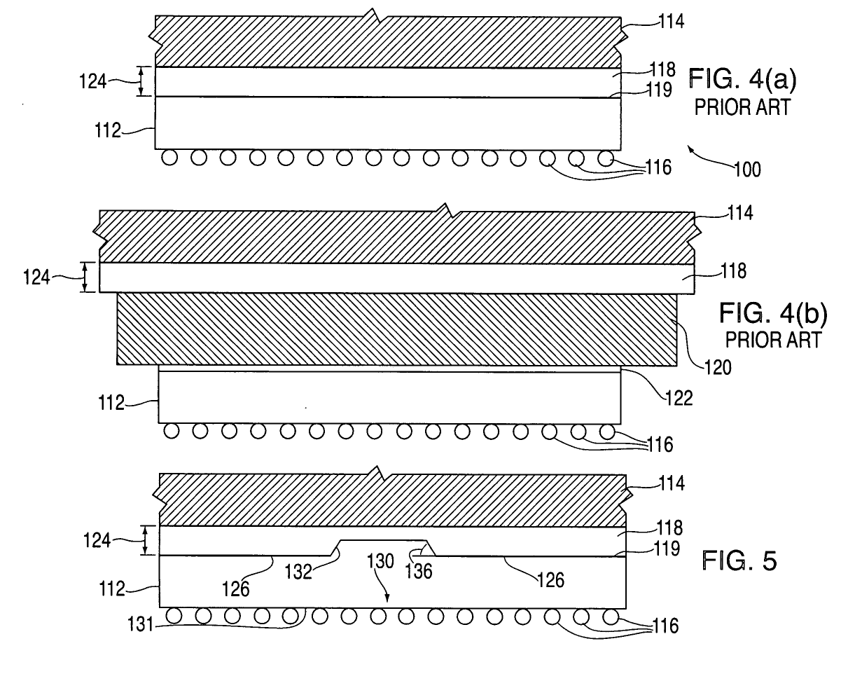

Referring now to FIGS. 4(a) and 4(b), a semiconductor package structure 100 is illustrated. Structure 100 includes a chip 112 that is in thermal communication with a substrate 114 on one surface, while an opposite surface is operably connected to a C4 array 116 for connection to a module (not shown). In an exemplary embodiment, substrate 114 is a heat sink, cold plate, or other suitable cooling means, or a lid, or heat pipe, or other intermediate structure which is in contact with a suitable cooling means. The main thermal dissipation path from chip 112 includes a thermal interface material (TIM) or thermal paste layer 118 which provides mechanical compliance and provides stress relief, between chip 112 and substrate or thermal cap/heat sink 114. The type of paste described in U.S. Pat. No. 5,098,609 can be used in the present invention, as can other compliant thermally conductive pastes used in the art or other compliant conformable thermally conductive materials. Furthermore, it is contemplated that TIM 118 includes a fluid when chip 112 is at operating temperature, such that phase change materials are contemplated.

For the case when the back surface 119 of chip 112 is substantially flat having no raised portions, the thermal paste layer 118, between the back surface 119 of the chip 112 and the structure 114, is about 70 percent of the internal thermal resistance, Rᵢₙₜ, if no thermal spreader is used and 114 is a lid or thermal hat. Rᵢₙₜ represents the internal thermal resistance of structure 100: the resistance through the chip 112, through the thermal interface material 118, and to the top surface of the lid structure 114, to which a cooling means is attached. When a thermal heat spreader 120 is attached with a thermally conductive adhesive, such as, but not limited to, for example, an Ag filled epoxy layer 122 to the back of the chip 112 as illustrated in FIG. 4(b), about 15 percent of Rᵢₙₜ is across the Ag epoxy layer 122 and about 40 percent of Rᵢₙₜ is across the thermal paste layer 118 between the thermal spreader 120 and to the bottom surface of the lid structure 114, to which a cooling means is attached. The thermal resistance of the paste layer 118 can be reduced by increasing the thermal conductivity of the paste 118, or by reducing the thickness 124 of the thermal paste layer 118. The thermal conductivity of the paste 118 is limited by the volume fraction which can be occupied by particles while still providing adequate mechanical compliance. If the paste layer 118 is not thick enough, and does not provide adequate compliance, the micro solder balls (C4s) 116 which provide electrical connections from the chip 112 to the module (not shown) can be crushed. Additionally, reducing the paste layer thickness 124 can cause an increase in “paste-pumping” which leads to a higher Rᵢₙₜ and potentially thermal failure of the chip 112. Paste pumping occurs when the paste 118 is displaced by air in a gap formed between the back surface 119 of the chip 112 and the thermal hat/heat 114 sink due to cyclic mechanical and/or thermal loads which forces the paste 118 out of the gap and where air, instead of paste 118, flows back into the gap when the load is removed. Paste pumping is most likely to occur with multichip modules due to the combination of vertical and horizontal deflections during cycling.

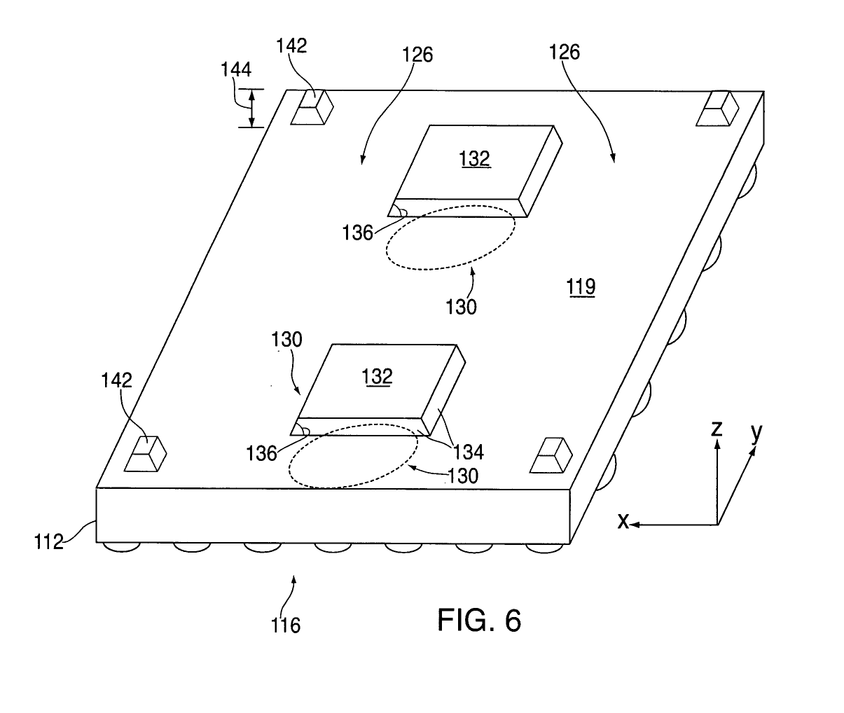

Referring now to FIG. 5, the invention is to locally vary the thickness of the compliant thermal paste layer 118 so that a “hot spot” 130 corresponding and aligned with an active area of chip 112 which has a higher than average power density is adequately cooled and the peak temperature on the chip surface 131 corresponding with the front of the chip having C4's attached is reduced. This is accomplished by patterning the back surface of the Si chip in contact with the thermal paste layer 118 and recessing portions of that surface 119 (or surfaces) in a pattern which corresponds to the cooler areas 126 on the chip (see FIG. 6). This results in a projecting “mesa” structure 132 being formed in the regions corresponding to the hot spot 130 on the chip so that after module assembly, the compliant thermal paste layer 118 is locally thinner over the “hot spot” 130. The local reduction of the Rᵢₙₜ will result in a corresponding reduction of the temperature of the hot spot 130. By locally reducing the paste layer thickness 124, the allowable global paste layer thickness can be increased, or kept the same, which will reduce the reliability risk of paste pumping and C4 crushing. Note that it is desirable not to form a mesa structure directly along any edges of the chip so that a region of thicker paste is formed which separates the thin layer of compliant thermally conductive material on the mesa from the edge of the chip and serves as a “dam” to prevent paste pumping and void formation in the thin layer of paste on top of the mesa. It is believed that for a paste layer about 100 microns thick, a gap of 1 mm would be an adequate separation between the mesa edge and the edge of the chip. The patterns formed can also be recessed to multiple depths if desired to allow more flexibility in adjusting the Rᵢₙₜ values as a function of location. This approach is most applicable to packaging structures where a relatively thick (greater than or equal to 25 micron) compliant thermally conductive material is used between the chip and the thermal hat/heat sink such as occurs in MCMs and with some SCMs.

The simplest implementation is to pattern the back surface 119 of a processor, or other, chip 112 while it is in wafer form as that is a batch process using available techniques and avoids the alignment issues present with patterning the thermal cap/heat sink 114, and additionally, fine features such as microstructure can be incorporated onto the mesa region as will be described further. Given that the desired feature sizes are larger than about 2-5 microns, a contact printer (not shown) can be used for backside lithographic processing on the wafer, which is less expensive than step and repeat exposure tools. In one exemplary embodiment, photolithography is used to pattern a masking layer such as silicon nitride on the back side of the wafer using reactive ion etching. The wafer is than mounted in a fixture which provides a liquid tight seal around the back edge of the wafer and a wet etch, such as TMAH (tetramethyl ammonium hydroxide) and water is used to etch the Si. Other suitable semiconductor substrate material/etchant combinations may also be used. The masking layer could be then removed using either a wet etch and the same fixture, or if desired, a dry etch step could be used. The depth of recess being contemplated is about 25 to about 75 microns (the current paste thickness is about 100+/−25 microns. The use of an anisotropic Si wet etch such as TMAH results in a tapered sidewall (at an angle 136 of about 55 degrees to the back surface 119 of chip 112) and facilitates the formation of self-terminated microstructures on the top surfaces of the mesas. Alternately, isotropic Si wet etches or Si dry etching is optionally used to form the mesa's, or the mesa's could be formed by a additive process where material such as a solder or metal is added to the back surface of the wafer discussed more fully hereinbelow.

In an exemplary embodiment with reference to FIG. 6, the raised portions or mesas 132 and other features are formed on the back surface 119 of the wafers prior to dicing using industry standard techniques such as photolithography and etching. More specifically, a contact printer is used to form the pattern on the back side 119 of the wafer which is aligned with an opposite front side having C4 array 116 such that recessed portions are formed in areas which correspond to the cooler areas 126 on the chip 112. If the semiconductor wafer is silicon, the silicon can be etched using either dry etching, isotropic wet etching, or anisotropic wet etching where anisotropic wet etching is the preferred method as this results in sloped sidewalls 134 on all the etched features which is desirable. Isotropic wet etching is preferred over highly directional dry etching as curved sidewalls result, with a radius of curvature approximately equal to the wet etch depth, as opposed to the vertical sidewalls which result from highly directional dry etching. When anisotropic silicon etching is used with a typical silicon wafer, the sloped sidewalls 134 form approximately a 55 degree angle indicated generally at 136 from surface 119 defining the wafer. A typical anisotropic etchant used is a solution of Tetramethyl ammonium hydroxide (TMAH) in water at a temperature of about 90° C. The resulting structure is illustrated in FIG. 6 where two mesas 132 are formed and aligned to hot-spot regions 130 (shown with oval phantom lines) on the front surface of the chip. Small raised portions 142 (i.e. support posts) disposed at the corners defining chip 112 are also formed to insure that a paste gap 144 is uni form when each chip 112 has an individual cooling piston (as described in U.S. Pat. No. 6,214,647) or heat sink 114 attached thereto. A typical thickness 124 for a layer of a compliant thermally conductive material 118 corresponding to paste gap 144 would be about 75 to about 150 microns and the desired corresponding raised portion or mesa 132 height would be about 50 to about 125 microns (i.e. about 25-50 microns less than the total gap thickness) with the raised features, 132, 142 covering a total area on the chip of about 25 percent or less.

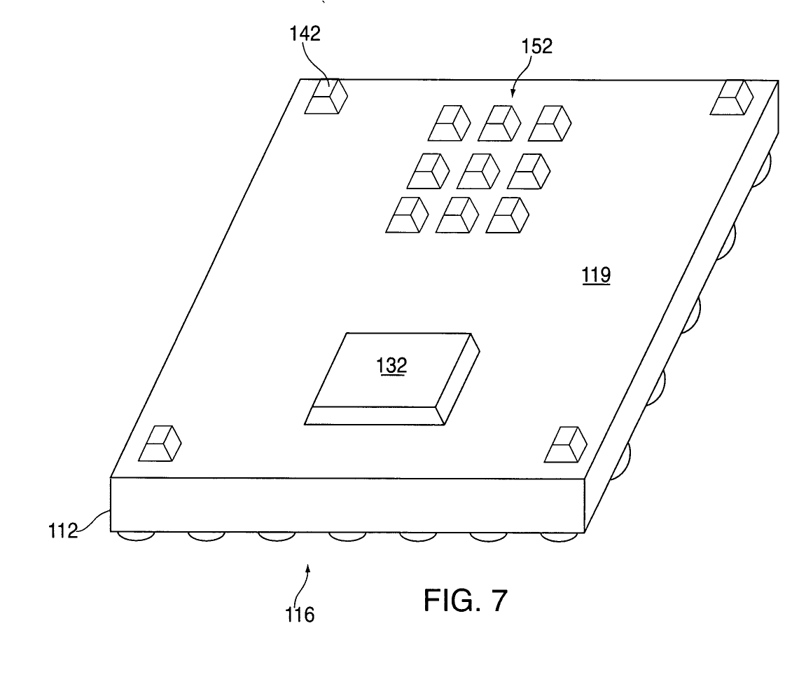

In an alternative embodiment shown schematically in FIG. 7, one of the solid mesas 132 is replaced with an array of smaller mesas 152 to form a composite mesa. This structure is advantageous when there are two hot spot regions 130 on the front surface of the chip 112 but one of them has a lower power density than the other. By using an array of smaller mesas 152, the thermal resistance through the compliant thermally conductive material 118 can be adjusted to an intermediate value between that of a solid mesa 132 and no mesa without additional processing steps as would be needed to produce mesa regions of different heights. The use of an array of small mesas 152 also reduces the likelihood of migration of the complaint thermally conductive material 118 as the maximum area of each individual mesa 152 is reduced.

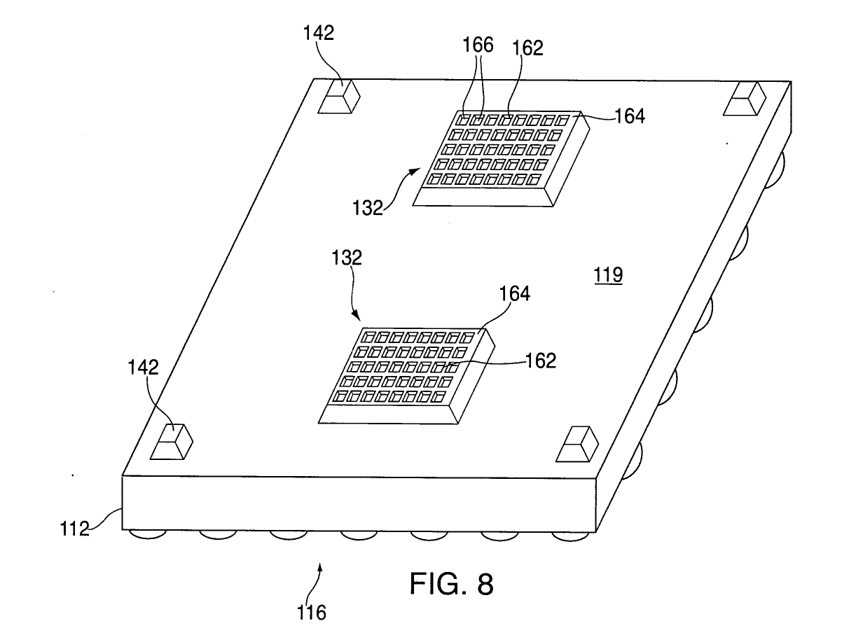

In a further alternative embodiment shown schematically in FIG. 8, a microstructure pattern 162, as previously disclosed in an application entitled “Improvement in chip cooling” having attorney docket number YOR920020329US1 filed on Dec. 27, 2002, contents of which are incorporated by reference, is added onto the top surface 164 of the mesa structures 132. YOR920020329US1 “Improvement in chip cooling” relates to cooling within integrated circuit (IC) packaging structures. In an integrated circuit package, a thermally conductive conformable material containing particles, such as a thermal interface material (TIM), or paste 118, is applied between the heat generating chip 112 and the heat sink or cold plate 114. A microstructure 162 is formed on at least one of the two nominally parallel surfaces which are in contact with the compliant thermal interface material 118 which is composed of a discrete pattern of sloped recesses 166. Alternatively, the microstructure 162 includes other structures including, but not limited to, grooves, for example. The largest particles in the compliant TIM 118 preferentially migrate downward into the recesses 166. The average thickness of the compliant TIM 118 is reduced below the diameter of the largest particles dispersed in the TIM 118, providing improved cooling. By proper design of the mask used for defining the regions to be anisotropically etched, this can be done with no additional processing steps.

A series of experiments was performed using single chip modules (SCM) and thermal test chips which were about 18×18 mm in size and had temperature monitors centered in each quadrant of the chip and were equipped with heaters to provide a uniform heat flux in each chip quadrant. Chips were fabricated with two mesas, each about 50 microns tall, in diagonally opposite chip quadrants where the size of the mesa was varied, either 4×4 or 6×6 mm, and the mesas were either solid (no microstructure) or were patterned with microstructure. The microstructure consisted of either what is referred to as “groove” microstructure which actually are a regular array of 10×10 micron pyramidal pits on 20 micron centers etched into the top surface of the mesa, or what is referred to as “half tone” microstructure which are actually a checkerboard pattern of 100×100 micron truncated pyramidal pits etched into the top surface of the mesa. By checkerboard, each 100×100 micron truncated (50 micron deep) pyramidal pits is surrounded on four sides by unetched regions and, with a slight separation, additional truncated pyramidal pits are diagonally adjacent. The parts were assembled with a nominal thermal paste layer thickness of 37.5 microns over the surface of the mesas and the corner support posts using thermal caps as described in U.S. Pat. No. 6,214,647. During the assembly and encapsulation process, the single chip modules were thermal cycled to cure a polymer sealant which attached the cap to the ceramic substrate on which the thermal chips were mounted. The thermal resistance measurements found that the average thermal resistance over a mesa was reduced by 22% compared to a site where there was no mesa. When the mesa had either the “grooved” or “half toned” microstructure, the average thermal resistance was reduced by 32% compared to the sites with no mesa. It should be noted that the measured thermal resistance includes not only the thermal resistance across the compliant thermal paste layer, but also includes the thermal resistance through the silicon chip and through the copper (Cu) lid structure. It is contemplated that the improved performance for the mesa structures with microstructure is perhaps due to reduced void formation during the assembly and encapsulation process. Alternatively, it is contemplated that the increased Si surface area in contact with the complaint thermal paste results in a reduction in the thermal interface resistance. As described previously, this is unlikely given the large bulk thermal resistance of the thermal paste compared to the bulk Si thermal resistance.

In further alternative embodiments, the raised mesa region(s) 132, 142, 152, 162 on the back (non-active) surface 119 of the chip 112 can be formed by an additive process such as by locally depositing, or depositing and patterning, metallic or other highly conductive layers. This could be done by electroplating in a masking layer of a dry film resist, for example.

If small gap technology is used as it is disclosed in U.S. Pat. No. 6,214,647, which is incorporated by reference herein in its entirety, it may be preferable to not form any structure on the piston which is used to adjust the gap as this could result in the piston tilting or could require the piston to be have a fixed rotation to correctly align which would reduce the ability of the piston to adjust for any tilt or height variation of the chip in setting the thermal paste gap. If structures are formed on a surface in contact with the piston, it maybe desirable to form small raised portions 142 at the corners of the chip 112 so as to insure that the paste gap 144 is uniform and the piston is not tilted relative to the surface which it is contacting.

None of the prior art known teaches locally reducing the thermal resistance as a function of location within a chip by structuring the back of the chip for a compliant thermal joint, but instead attempts to reduce the overall thermal resistance. The above described disclosure describes an apparatus and method for reducing the peak temperature on a chip with a compliant thermal joint. In an exemplary embodiment, the temperature of the “hot spot” is reduced by locally reducing the compliant paste layer thickness aligned therewith. The above described disclosure further details an apparatus and method to counter a critical thickness or a limit of how thin a compliant thermal interface material (TIM) layer disposed between the chip and substrate may be with a MCM. This critical thickness is a function of the amount of horizontal and vertical expansion/contraction present, chip size, and the TIM properties. The use of a raised portion or “mesa” as disclosed above, especially with microstructure on the mesa, allows a local reduction of the paste thickness without failure due to paste pumping if the area of the mesa is less than or equal to about 25 percent of the total chip surface area and not located directly along a chip edge, so that a “dam” of normal thickness paste is formed before the free edge to reduce pumping. More specifically, an edge defining each raised portion 132 and interfaced with back surface 119 of chip 112 is at least 1 mm away from an edge defining chip 112.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

1. A semiconductor packaging structure comprising:
a substrate; and
a semiconductor chip in thermal communication with the substrate, the chip having at least one region of locally higher power density on an active front surface of the chip where at least one raised portion is defined on a back surface of the chip aligned to the high power region on the front surface of the chip and wherein the back surface of the chip and facing surface of the substrate are separated from each other by a continuous layer of a compliant thermally conductive material having a single composition.

2. The structure of claim 1, wherein the substrate includes one of a heat sink, a cooling plate, a thermal spreader, a heat pipe, a thermal hat, and a package lid.

3. The structure of claim 1, wherein said at least one raised portion is formed by etching material which is aligned to at least one of the high power region on the front surface of the chip and an area on the chip having a function critical to server reliability although not necessarily having a heat flux higher than an average heat flux of the chip.

4. The structure of claim 1, wherein a support post is formed on at least one of each corner and side defining the chip so that the compliant thermally conductive material layer is uniformly formed between the chip and the substrate.

5. The structure of claim 1, wherein an array of raised portions are aligned to the at least one region of locally higher power density on the active front surface of the chip.

6. The structure of claim 1, wherein a top surface defining the at least one raised portion is provided with a discretely shaped recessed microstructure.

7. The structure of claim 1, wherein the at least one raised portion is formed by anisotropic etching of the back surface of the chip.

8. The structure of claim 1, wherein an edge defining each of the at least one raised portion is at least 1 mm away from an edge defining the chip.

9. The structure of claim 1, wherein said at least one raised portion is formed by an additive process on the back surface of the chip.

10. The structure of claim 9, wherein the additive process includes at least one of a metallic layer and a thermally conductive layer.

11. The structure of claim 10, wherein the additive process includes at least one of locally depositing, depositing and patterning, and electroplating in a masking layer of a dry film resist for the thermally conductive layer.

12. The structure of claim 1, wherein an area occupied by the at least one raised portion on the back surface of the chip is less than or equal to 25 percent of a total surface area of the back surface.

13. A method of semiconductor packaging comprising:
configuring at least one raised portion defining at least one of a substrate and a back surface of a chip aligned to a high power region on the front surface of the chip, the high power region corresponding to at least one of an area on the chip having a function critical to system reliability although not necessarily having a heat flux higher than an average heat flux of the chip and to at least one region of locally higher power density on an active front surface of the chip; and
disposing a continuous layer of a compliant thermally conductive material having a single composition intermediate the back surface of the chip and facing surface of the substrate.

14. The method of claim 13, wherein the substrate includes one of a heat sink, a cooling plate, a thermal spreader, a heat pipe, a thermal hat, and a package lid.

15. The structure of claim 13, wherein said at least one raised portion is formed by at least one of etching material which is aligned to the high power region on the front surface of the chip and by an additive process on the back surface of the chip.

16. The method of claim 15, wherein a top surface defining the at least one raised portion is provided with a discretely shaped recessed microstructure.

17. The method of claim 13, further comprising;
forming a support post is on at least one of each corner and side defining the chip so that the compliant thermally conductive material layer is uniformly formed between the chip and the substrate.

18. The method of claim 13, wherein an array of raised portions are aligned to at least one of the at least one region of locally higher power density on the active front surface of the chip and an area on the chip having a function critical to system reliability although not necessarily having a heat flux higher than an average heat flux of the chip.

19. The method of claim 13, wherein an edge defining each of the at least one raised portion is at least 1 mm away from an edge defining the chip.

20. The method of claim, 13 wherein an area occupied by the at least one raised portion on the back surface of the chip is less than or equal to 25 percent of a total surface area of the back surface.
